(19) United States
(12) Patent Application Publication
(10) Pub. No.: US 2007/0096208 A1
(43) Pub. Date: May 3, 2007

(54) Manufacturing method for flat panel display

(76) Inventors: Woo-jae Lee, Gyeonggi-do (KR); Myeong-hee Kim, Seoul (KR); Seung-jin Baek, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/584,131

(22) Filed: Oct. 20, 2006

(30) Foreign Application Priority Data
Oct. 21, 2005 (KR) 2005-0099486

(51) Int. Cl. H01L 27/12; H01L 27/01; H01L 21/84; H01L 21/00; H01L 31/0392

(52) U.S. Cl. 257/347; 438/149

(57) ABSTRACT

A dummy glass substrate supporting a plastic insulation substrate for a display apparatus wherein the dummy glass substrate includes a stress relaxation portion having grooves that reduce thermal deformation of the plastic insulation substrate.

### CROSS-REFERENCE TO RELATED APPLICATIONS

This application claims priority from Korean Patent Application No. 2005-0099486, filed on Oct. 21, 2005, in the Korean Intellectual Property Office, the disclosure of which is incorporated herein by reference.

### FIELD OF THE INVENTION

The present invention relates to a dummy glass substrate and a method for manufacturing a display apparatus using the same, and more particularly, to a dummy glass substrate having a stress relaxation portion formed with a groove and a display apparatus manufacturing method using the dummy glass substrate.

### DESCRIPTION OF THE RELATED ART

Flat panel displays, such as the liquid crystal display (LCD) and the organic light emitting diode (OLED) display are replacing cathode ray tube displays. The LCD includes a first substrate having thin film transistors, a second substrate arranged facing the first substrate, and an LCD panel having a liquid crystal layer interposed between the first and second substrates. The LCD panel may include a backlight unit since the LCD is a non-light emitting element. The amount of light emitted from the backlight unit is determined by the orientation of the crystals in the liquid crystal layer.

The LCD includes a driving circuit for applying driving signals to gate lines and data lines arranged in the first substrate. The driving circuit includes a gate driving chip, a data driving chip, and a printed circuit board (PCB) provided with a timing controller and a driving voltage generator. An organic light emitting diode (OLED) includes a light emitting layer that emits light by combining holes and electrons implanted from a pixel electrode and a common electrode, respectively. The OLED provides a superior viewing angle and has the advantage that a backlight unit is not required.

Recently, a plastic insulation substrate has been widely used, replacing the conventional glass insulation substrate so that flat panel displays can be made thinner and lighter in weight. The thin plastic insulation substrate has the problem of being easily deformable, especially by heat, and thus needs to be backed by a supporting member such as a dummy glass substrate, a special use stainless steel (SUS) substrate, or a plastic substrate. However, it is difficult to apply a spin process to the SUS substrate since the SUS substrate is relatively heavy even though made as thin as possible. The plastic substrate needs to be quite thick to be used as the supporting member and is also likely to be deformed by high temperatures.

The dummy glass substrate is flat and is resistive to heat and chemicals. If a plastic insulation substrate is attached to a dummy glass substrate, the manufacturing process requires a high temperature process and a low temperature process. However, deformation of the plastic insulation substrate may occur due to different coefficients of thermal expansion (CTE) of the glass and the plastic, i.e., a so-called bimetal effect occurs between the plastic insulation substrate and the dummy glass substrate.

### SUMMARY OF THE INVENTION

The present invention overcomes certain of the above problems by providing a dummy glass substrate supporting a plastic insulation substrate wherein the dummy glass substrate includes a stress relaxation portion having plurality of grooves. Each grove has a depth which corresponds to 0.1% to 25% of the thickness of the dummy glass substrate. In an illustrative embodiment, the width of each groove ranges from 5 μm to 50 μm and the groove is formed in a dotted groove pattern wherein the size of each dotted groove ranges from 0.1 mm×0.1 mm to 10 mm×10 mm and may be of rectangular or hexagonal shape and may have a rectangular or V-shaped cross sections.

In one embodiment, the dummy glass substrate will include a plurality of such grooves formed in parallel. In another embodiment the dummy glass substrate will include two sets of mutually parallel grooves formed perpendicular to each other across one surface of the substrate.

The display apparatus of the invention may be manufactured by the following steps: preparing a dummy glass substrate having a stress relaxation portion in which a groove is formed; adhering one side of a plastic insulation substrate to the stress relaxation portion of the dummy glass substrate; forming a display element on the other side of the plastic insulation substrate; and detaching the dummy glass substrate from the plastic insulation substrate. According to an aspect of the present invention, the adhesive has the characteristic of being detachable at a low temperature.

### BRIEF DESCRIPTION OF THE DRAWING

The above and/or other aspects and advantages of the prevent invention will become apparent and more readily appreciated from the following description of the exemplary embodiments, taken in conjunction with the accompany drawings, in which:

FIG. 1 is a perspective view of a dummy glass substrate according to a first exemplary embodiment of the present invention;

FIG. 2A to FIG. 2C are sectional views showing a method for manufacturing a display apparatus using the dummy glass substrate according to the first exemplary embodiment of the present invention;

FIG. 3 shows deformation of a plastic substrate of a display apparatus during a manufacturing process.

FIG. 4 is a perspective view of a dummy glass substrate according to a second exemplary embodiment of the present invention;

FIG. 5 to FIG. 7 are top plane views showing dummy glass substrates according to third, fourth, and fifth exemplary embodiments of the present invention, respectively.

### DESCRIPTION

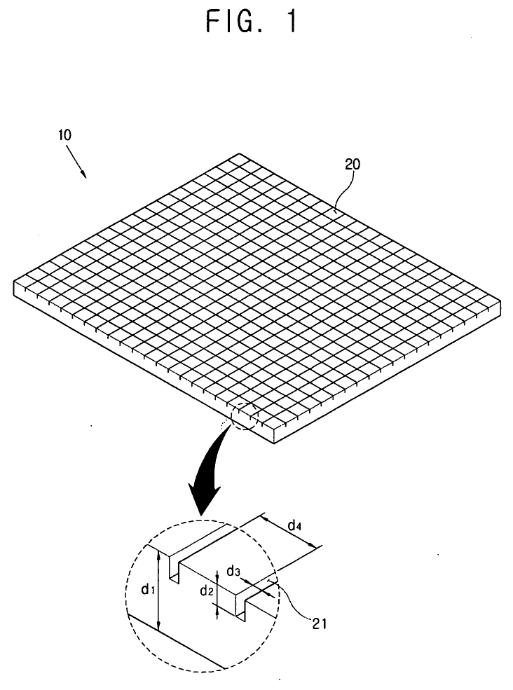

Referring to FIG. 1, a perspective view of a dummy glass substrate according to the first exemplary embodiment of the present invention is shown. Dummy glass substrate 10 may be formed in a square plate shape, with a thickness d1 of 0.7 to 1.1 mm. One side of the dummy glass substrate 10 is formed with a stress relaxation surface 20. A plurality of grooves such as groove 21, are formed in the stress relaxation surface 20. Grooves such as groove 21 extend longitudinally and transversely over the entire surface of the stress relaxation surface 20 and divides the stress relaxation surface 20 into a plurality of squares as shown in isometric view in FIG. 1. Each groove 21 has a rectangular shaped cross section, and the depth d2 of the groove 12 may be about 0.1% to 25% of the height d1 of the dummy glass substrate 10.

It has been found that the stress relaxation effect becomes insignificant and the manufacturing process becomes complicated when the depth d2 (FIG. 1) of groove 21 is less than 0.1% of the thickness d1 of dummy glass substrate 10. When the depth d2 of groove 21 is greater than 25% of the height d1 of the dummy glass substrate 10, the strength of the dummy glass substrate 10 may be adversely affected. The interval d4 between the respective adjacent grooves 21 arranged in parallel may be about 0.1 mm to 10 mm. The width d3 of groove 21 may be about 5 μm to 50 μm. When the width d3 of groove 21 is less than 5 μm, the stress relaxation effect becomes insignificant. When the width d3 of groove 21 is greater than 50 μm, processing fluids such as cleansing water or etching water may reduce the adhesion between the plastic insulation substrate 21 and the dummy glass substrate 10. Groove 21 may be formed by performing a photolithographic process or a laser process on the dummy glass substrate 10.

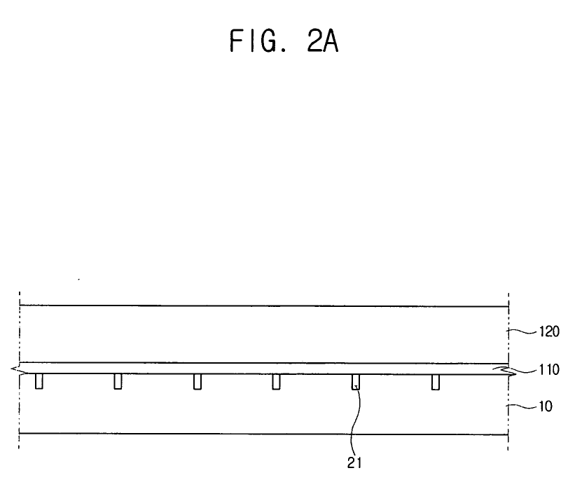

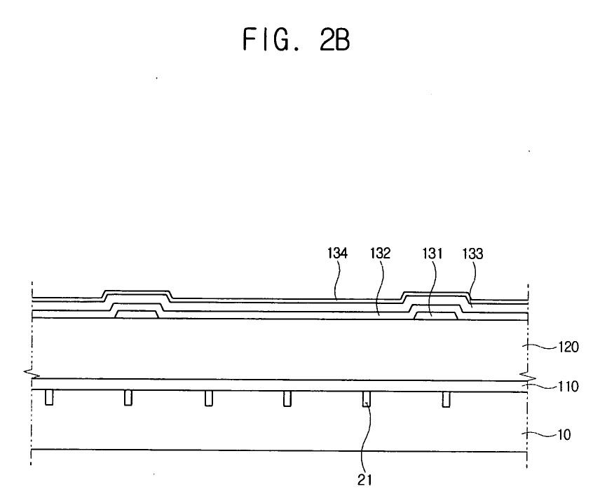

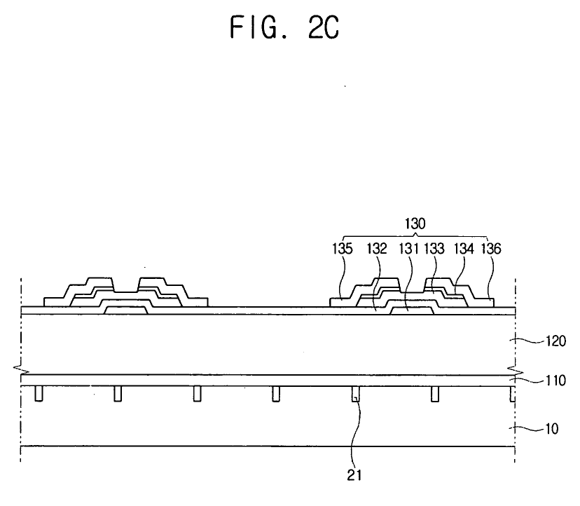

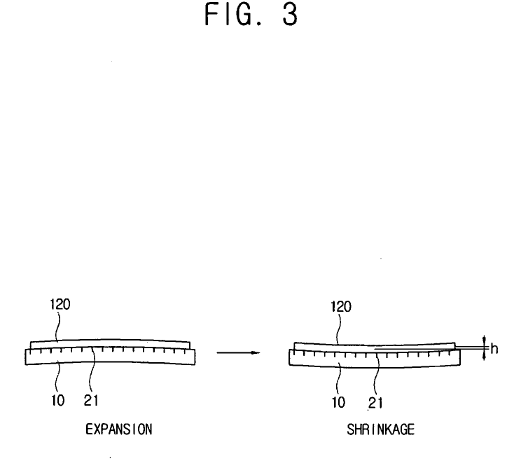

A method for manufacturing the dummy glass substrate according to the first exemplary embodiment of the present invention will now be described with reference to FIG. 2A to FIG. 2C, and FIG. 3. Amorphous silicon (a-Si) thin film transistor, a poly silicon thin film transistor, an organic semiconductor thin film transistor, and a color filter, etc., may be formed on the plastic insulation layer to be formed on the stress relaxation surface 20 of dummy glass substrate 10. A plastic insulation substrate 120 is adhered on the stress relaxation surface 20 of the dummy glass substrate 10 using an adhesive 110 as shown in FIG. 2A. The dummy glass substrate 10 and the plastic insulation substrate 120 are adhered to each other by coating one surface of the plastic insulation substrate 120 with the adhesive 110 and then attaching the surface of substrate 120 coated with the adhesive 110 to the dummy glass substrate 10. Plastic insulation substrate 120 may be made of polycarbon, polyimide, polyethersulfone (PES), polyacrylate (PAR), polyethylenenaphthalate (PEN), and polyethylene terephthalate (PET), etc.

The thickness of the plastic insulation substrate 120 may range from about 0.05 mm to 0.2 mm. When using the plastic insulation substrate 120, the processing temperature should be within an allowable thermal range of 150 to 200° C., as lower temperatures may adversely affect adhesion. When the dummy glass substrate 10 and the plastic insulation substrate 120 are adhered to one another, there is no adhesion where grooves 21 are present.

As shown in FIG. 2B, gate line 131, gate insulation layer 132, semiconductor layer 133, and a resistance contact layer 134 are formed on the plastic insulation layer 120. The gate insulation layer 132, the semiconductor layer 133, and the resistance contact layer 134 are formed consecutively using chemical vapor deposition (CVD). The three consecutive layers are formed at a relatively high temperature, and accordingly, the plastic insulation substrate 120 may be deformed due to the different thermal expansion coefficients of the substrate 120 and the dummy glass substrate 10. Such a deformation of the plastic insulation substrate 120 would ordinarily affect a display element (e.g. a thin film transistor), and furthermore, the deformation might cause the thin films found on substrate 120 to lift away from the plastic insulation substrate 120. However, this condition is avoided by the present embodiment.

Referring to FIG. 3, when heat is applied, the dummy glass substrate 10 and the plastic insulation substrate 120 both expand. Since the thermal expansion coefficient of the plastic insulation substrate 120 is greater than that of the dummy glass substrate 10, a center portion of the plastic insulation substrate 120 is bent upward. The thermal expansion coefficient of the plastic insulation substrate 120 may be more than 10 to 30 times that of the dummy glass substrate 10. Such an expansion may cause a problem when the process temperature exceeds 130° C.

On the other hand, the dummy glass substrate 10 and the plastic insulation substrate 120 both shrink at cold temperatures. During the cooling process, moisture or air may penetrate into the plastic insulation substrate 120, thereby accelerating the shrinkage of the plastic insulation substrate 120. Accordingly, the center portion of the plastic insulation substrate 120 is bent downward. The amount of bending at the center portion of the insulation substrate 120 may be defined as the difference in height n of the center portion with respect to an edge portion of the plastic insulation substrate 120. Accurate deposition of the display elements becomes difficult when the plastic insulation substrate 120 is deformed, and the thin film formed on the plastic insulation substrate 120 may lift away due to the expansion and shrinkage. The deformation of the plastic insulation substrate 120 is caused by the “bimetal effect” occurring between the dummy glass substrate 10 and the plastic insulation substrate 120.

According to the embodiment of the present invention, the plastic insulation substrate 120 and the dummy glass substrate 10 are partially separated due to the presence of grooves such as groove 21. Grooves 21 significantly reduce deformation of the dummy grass substrate 120 by relaxing stress applied to the dummy glass substrate during the expansion and shrinkage. As the dummy glass substrate 10 is less deformed, the plastic insulation substrate 120 adhered to the stress relaxation surface 20 is deformed less. Subsequently, the semiconductor layer 133 and the resistance contact layer 134 are patterned and a source electrode 135 and a drain electrode 135 are formed, to thereby complete the thin film transistor 130 (FIG. 2C.

An organic light emitting apparatus may be manufactured by forming a pixel electrode, an organic light emission layer, and a common electrode on the thin film transistor 130, or a liquid crystal display apparatus may be manufactured by forming a pixel electrode on the thin film transistor 130 and then coupling the thin film transistor 130 with another substrate.

After the thin film transistor 130 is formed, grooves 21 will relax the stress applied to the dummy glass substrate 10, thereby reducing deformation of the plastic insulation substrate 120.

Table 1 shows a measurement result of a deformation amount of the plastic insulation substrate 120 using the dummy glass substrate 10. The dummy glass substrate 120 used for this measurement has a thickness d1 of 1.1 mm and was of 300 mm*400 mm. Grooves 21 are arranged at the interval d4 of 5 mm, and each has a depth d2 of 10 μm and a width d3 of 10 μm. The measuring of the deformation amount h of the plastic insulation substrate was performed after heating the dummy glass substrate 10 and the plastic insulation substrate 120 at 150° C. for about 10 minutes and cooling the substrates at the normal temperature.

TABLE 1

| | Embodiment | Sample 1 | Sample 2 |
|---|---|---|---|
| Condition | Adhesion to | No groove | Adhesion to opposite |
| | stress relax- | | surface of stress |
| | ation surface | | relaxation surface |
| Deformation(mm) | 1.69 | 2.58 | 2.46 |

As shown in Table 1, the deformation amount of the plastic insulation substrate is 2.58 mm (Sample 1) when using a dummy glass substrate having no groove formed therein. When the plastic insulation substrate is adhered to an opposite surface to the stress relaxation surface of the dummy glass substrate (Sample 2), the deformation amount of the plastic insulation substrate becomes 2.46 mm. The two comparison results are not greatly different from each other. However, when the plastic insulation substrate is adhered to the stress relaxation substrate where the grooves are formed (the “Embodiment”), the deformation amount becomes 1.69 mm, which is 35% less than the above results.

The shape of each groove of the first exemplary embodiment may vary depending on the size of the dummy glass substrate, the adhesive force between the plastic insulation substrate and the dummy glass substrate, and the deformation amount of the plastic insulation substrate.

The following second to fifth exemplary embodiments of the present inventions show variation of the shape of the groove.

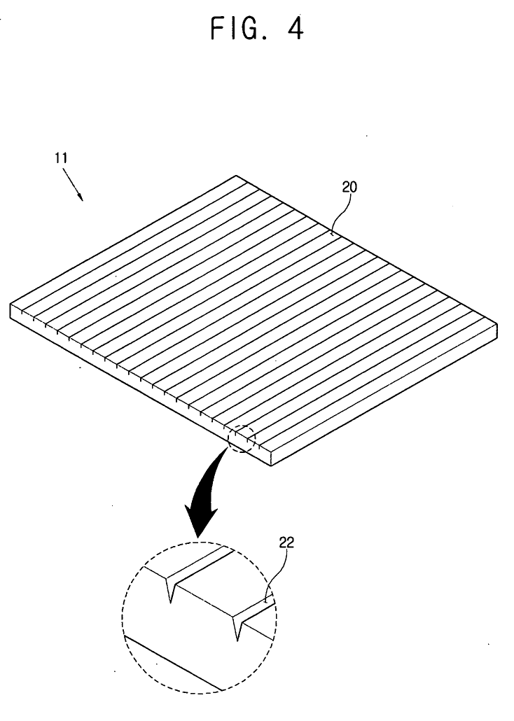

FIG. 4 is a perspective view of a dummy glass substrate according to the second exemplary embodiment of the present invention. Grooves 22 are arranged in parallel on a dummy glass substrate 11 according to the second exemplary embodiment of the present invention, and each groove 22 has a “V” shaped cross-section. The respective grooves 22 may be manufactured by a photo-lithographic etching process or by a mechanical process.

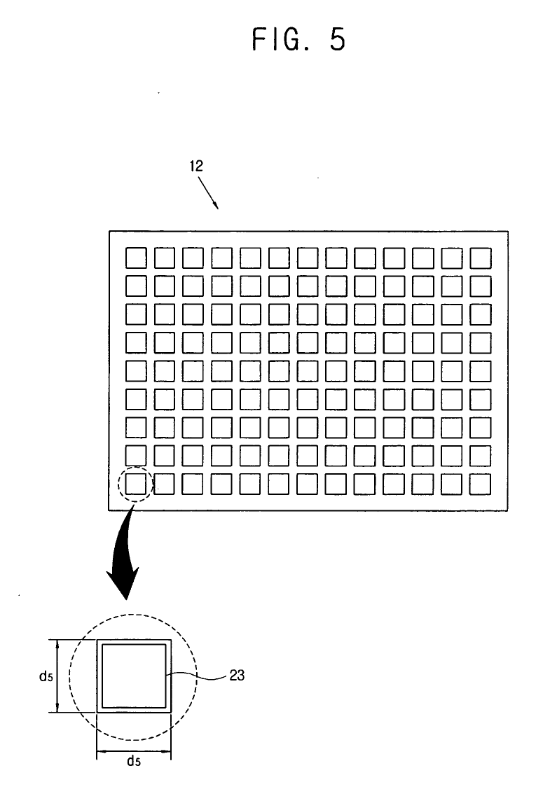

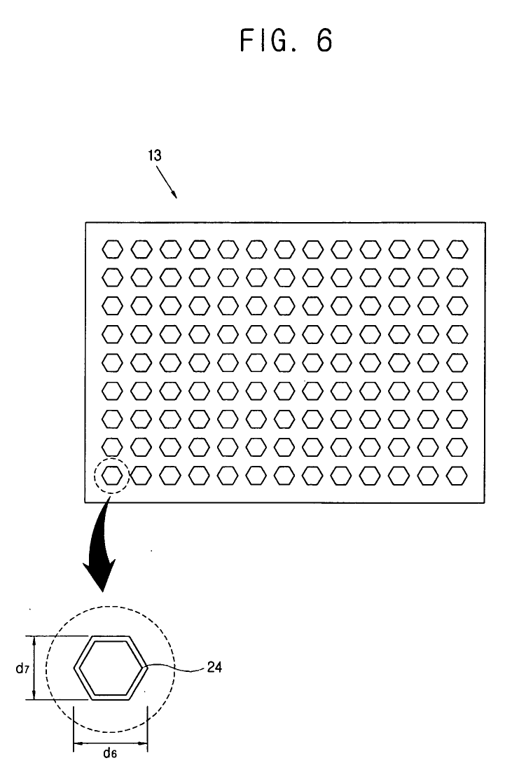

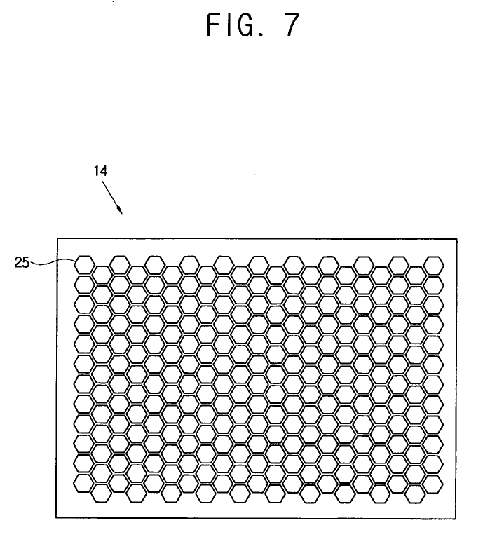

FIG. 5 to FIG. 7 are top plan views of dummy glass substrates according to the third to fifth exemplary embodiments of the present invention, respectively. Grooves 23, each in a square shape, are regularly arranged on a dummy glass substrate 12 according to the third exemplary embodiment of the present invention as shown in FIG. 5. Each side of the respective groove 23 is about 0.1 mm to 10 mm. Grooves 24, each having a regular hexagon shape, are regularly arranged on a dummy glass substrate 13 according to the fourth exemplary embodiment of the present invention as shown in FIG. 6. The size d6×d7 of each groove 24 is about 0.1 mm to 10 mm. Grooves 25, each in a hexagonal shape, are arranged in a honeycomb shape on a dummy glass substrate 14 according to the fifth exemplary embodiment of the present invention as shown in FIG. 7.

As described above, the present invention provides a dummy glass substrate for reducing deformation of a plastic insulation substrate during a display apparatus manufacturing process. In addition, the present invention provides a method for manufacturing a display apparatus for reducing deformation of a plastic insulation substrate.

Although a few exemplary embodiments of the present invention have been shown and described, it will be appreciated by those skilled in the art that changes may be made in these embodiments without, however, departing from the spirit and scope of the invention.

What is claimed is:

1. A dummy glass substrate for supporting a plastic insulation substrate, the dummy glass substrate comprising a stress relaxation portion in which at least one groove is formed.

2. The dummy glass substrate of claim 1, wherein each groove is formed across the entire surface of the stress relaxation portion.

3. The dummy glass substrate of claim 1, wherein the depth of each groove corresponds to 0.1% to 25% of the thickness of the dummy glass substrate.

4. The dummy glass substrate of claim 1, wherein the width of each groove is 5 μm to 50 μm.

5. The dummy glass substrate of claim 1, wherein each groove is formed in a dotted groove pattern, each dotted groove pattern comprising a depressed dot-shaped region on one surface of said substrate.

6. The dummy glass substrate of claim 5, wherein the size of each dotted groove pattern is approximately 0.1 mm×0.1 mm to 10 mm×10 mm.

7. The dummy glass substrate of claim 5, wherein each dotted groove pattern has one of rectangular and hexagonal shapes.

8. The dummy glass substrate of claim 1, wherein the groove has one of rectangular and V-shaped cross sections.

9. A method for manufacturing a display apparatus comprising:
preparing a dummy glass substrate having a stress relaxation portion in which at least one groove is formed;
adhering one side of a plastic insulation substrate to the stress relaxation portion of the dummy glass substrate;
forming a display element on the other side of the plastic insulation substrate; and
detaching the dummy glass substrate from the plastic insulation substrate.

10. The method of claim 9, wherein the adhering comprises coating an adhesive to at least one of the stress relaxation portion of the dummy glass substrate and the plastic insulation substrate.

11. The method of claim 10, wherein the adhesive becomes detached at a low temperature.

12. The method of claim 9, wherein the groove is formed over the entire surface of the stress relaxation portion.

13. The method of claim 9, wherein the depth of the groove corresponds to 0.1% to 25% of the thickness of the dummy glass substrate.

14. The method of claim 9, wherein the width of the groove is 5 μm to 50 μm.

15. The method of claim 9, wherein the at least one groove is formed in a dotted groove pattern.

16. The method of claim 15, wherein the size of each dotted groove is 0.1 mm×0.1 to 10 mm×10 mm.

17. The method of claim 15, wherein each dotted groove comprises one of rectangular and hexagonal shapes.

18. The method of claim 9, wherein the at least one groove comprises one of rectangular and V-shaped cross sections.

19. The method of claim 9, wherein the display element comprises a thin film transistor.
